(19) United States
(12) Patent Application Publication
(10) Pub. No.: US 2015/0162912 A1
(43) Pub. Date: Jun. 11, 2015

(54) LEVEL SHIFTER

(71) Applicant: Orise Technology Co., Ltd., Hsinchu City (TW)

(72) Inventors: Kun-Tsung Lin, Hsinchu City (TW); Kuan-Han Chen, Hsinchu City (TW)

(21) Appl. No.: 14/564,612

(22) Filed: Dec. 9, 2014

(30) Foreign Application Priority Data
Dec. 11, 2013 (TW) 102145725

(51) Int. Cl. H03K 19/0185; H03K 3/012

(52) U.S. Cl. CPC H03K 19/018521; H03K 3/012

(57) ABSTRACT

A level shifter includes a first transistor, a second transistor, a third transistor, a fourth transistor, and a switching element. The first transistor is connected to a first node, the input signal and a first power supply voltage. The second transistor is connected to a second node, an inverted input signal and the first power supply voltage. The third transistor is connected to a second power supply voltage, the first node and the second node. The fourth transistor is connected to the second power supply voltage, the second node and the first node. The switching element is connected between the first node and the second node. When a voltage level of the input signal is changed, the switching element is turned on for a time interval according to the enabling signal, so that a voltage level of the output signal is changed.

This application claims the benefit of Taiwan Patent Application No. 102145725, filed Dec. 11, 2013, the subject matter of which is incorporated herein by reference.

### FIELD OF THE INVENTION

The present invention relates to a level shifter, and more particularly to a level shifter with a reduced layout area.

### BACKGROUND OF THE INVENTION

A level shifter is used for converting a narrow-range input signal into a wide-range output signal. Consequently, the level shifter is an important part of an interface circuit. For example, in a source driver chip of a display panel, a control signal is originally in the range between 0 and 1.5 volts. However, when the control signal is outputted to a source terminal of the display panel, the voltage is in the range between 0 and 5 volts. Conventionally, by the level shifter, the input signal in the range between 0 and 1.5 volts is converted into the output voltage in the range between 0 and 5 volts.

FIG. 1A is a schematic circuit diagram illustrating a conventional level shifter. FIG. 1B is a schematic timing waveform diagram illustrating associated signal processed by the conventional level shifter. The level shifter 10 is used for converting an input signal IN (in the range between the voltage VDD1 and the voltage GND) into an output voltage OUT (in the range between the voltage VDD2 and the voltage GND). The voltage VDD1 is a first power supply voltage (e.g. 1.5V), the voltage VDD2 is a second power supply voltage (e.g. 5V), and the voltage GND is a ground voltage (e.g. 0V). The second power supply voltage VDD2 is higher than the first power supply voltage VDD1, and the first power supply voltage VDD1 is higher than the ground voltage GND.

As shown in FIG. 1A, the level shifter 10 comprises a first P-type transistor MP1, a second P-type transistor MP2, a first N-type transistor MN1, and a second N-type transistor MN2. The source terminal of the first P-type transistor MP1 is connected to the second power supply voltage VDD2. The drain terminal of the first P-type transistor MP1 is connected to a first node (a). The gate terminal of the first P-type transistor MP1 is connected to a second node (b). The source terminal of the second P-type transistor MP2 is connected to the second power supply voltage VDD2. The drain terminal of the second P-type transistor MP2 is connected to the second node (b). The gate terminal of the second P-type transistor MP2 is connected to the first node (a).

The drain terminal of the first N-type transistor MN1 is connected to the first node (a). The source terminal of the first N-type transistor MN1 is connected to the ground voltage GND. The gate terminal of the first N-type transistor MN1 receives the input signal IN. The drain terminal of the second N-type transistor MN2 is connected to the second node (b). The source terminal of the second N-type transistor MN2 is connected to the ground voltage GND. The gate terminal of the second N-type transistor MN2 receives an inverted input signal INB. The first node (a) is served as a first output terminal and generates an inverted output signal OUTB. The second node (b) is served as a second output terminal and generates the output signal OUT.

In case that the input signal IN is 1.5V and the inverted input signal INB is 0V, the first N-type transistor MN1 and the second P-type transistor MP2 are turned on, and the second N-type transistor MN2 and the first P-type transistor MP1 are turned off. Consequently, the magnitude of the output signal OUT is equal to the magnitude of the second power supply voltage VDD2 (i.e. 5V), and the magnitude of the inverted output signal OUTB is equal to magnitude of the ground voltage GND (i.e. 0V).

In case that the input signal IN is 0V and the inverted input signal INB is 1.5V, the first N-type transistor MN1 and the second P-type transistor MP2 are turned off, and the second N-type transistor MN2 and the first P-type transistor MP1 are turned on. Consequently, the magnitude of the output signal OUT is equal to the magnitude of the ground voltage GND (i.e. 0V), and the magnitude of the inverted output signal OUTB is equal to magnitude of the second power supply voltage VDD2 (i.e. 5V).

As known, the conventional level shifter 10 has some drawbacks. For example, the layout area is very large, the transition period of the output signal OUT is too long, and the power consumption is too high. The reasons will be illustrated as follows.

Please refer to FIG. 1B. During the period of changing the input signal IN from 1.5V from 0V and changing the inverted input signal INB from 0V to 1.5V, the second N-type transistor MN2 and the second P-type transistor MP2 are simultaneously turned on. Under this circumstance, a short-circuit current (Is) is generated.

Moreover, for smoothly resulting in the transition of the output signal OUT and the inverted output signal OUTB, the first N-type transistor MN1 and second N-type transistor MN2 should have large sizes in order to provide large driving strength. In other words, the size ratio of the N-type transistor to the P-type transistor of the conventional level shifter 10 should be specially designed. Moreover, the size of the N-type transistor is larger than the size of the P-type transistor.

Due to the above design, the layout area of the whole level shifter 10 too large, the transition period of the output signal OUT is too long, and the short-circuit current is too large.

As shown in FIG. 1B, the transition period Tt of the output signal OUT and the inverted output signal OUTB is 19 ns, the maximum value of the short-circuit current is about 50 μA, and the average short-circuit current is about 15.4 μA.

### SUMMARY OF THE INVENTION

An embodiment of the present invention provides a level shifter for converting an input signal into an output signal. The level shifter includes a first transistor, a second transistor, a third transistor, a fourth transistor, and a switching element. The first transistor has a first drain terminal connected to a first node, a first gate terminal receiving the input signal, and a first source terminal connected to a first power supply voltage. The second transistor has a second drain terminal connected to a second node, a second gate terminal receiving an inverted input signal, and a second source terminal connected to the first power supply voltage. The third transistor has a third source terminal connected to a second power supply voltage, a third drain terminal connected to the first node, and a third gate terminal connected to the second node. The fourth transistor has a fourth source terminal connected to the second power supply voltage, a fourth drain terminal connected to the second node, and a fourth gate terminal connected to the first node. The first node is served as a first output terminal for generating an inverted output signal. The second node is served as a second output terminal for generating the output signal. The switching element is connected between the first node and the second node. The switching element is controlled according to an enabling signal. When a voltage level of the input signal is changed, the switching element is turned on for a time interval according to the enabling signal, so that a voltage level of the output signal is changed.

Numerous objects, features and advantages of the present invention will be readily apparent upon a reading of the following detailed description of embodiments of the present invention when taken in conjunction with the accompanying drawings. However, the drawings employed herein are for the purpose of descriptions and should not be regarded as limiting.

### BRIEF DESCRIPTION OF THE DRAWINGS

The above objects and advantages of the present invention will become more readily apparent to those ordinarily skilled in the art after reviewing the following detailed description and accompanying drawings, in which:

FIG. 1A (prior art) is a schematic circuit diagram illustrating a conventional level shifter;

FIG. 1B (prior art) is a schematic timing waveform diagram illustrating associated signal processed by the conventional level shifter;

FIG. 2A is a schematic circuit diagram illustrating a level shifter according to a first embodiment of the present invention;

FIG. 2B is a schematic timing waveform diagram illustrating associated signal processed by the level shifter of FIG. 2A; and

FIG. 3 is a schematic circuit diagram illustrating a level shifter according to a second embodiment of the present invention.

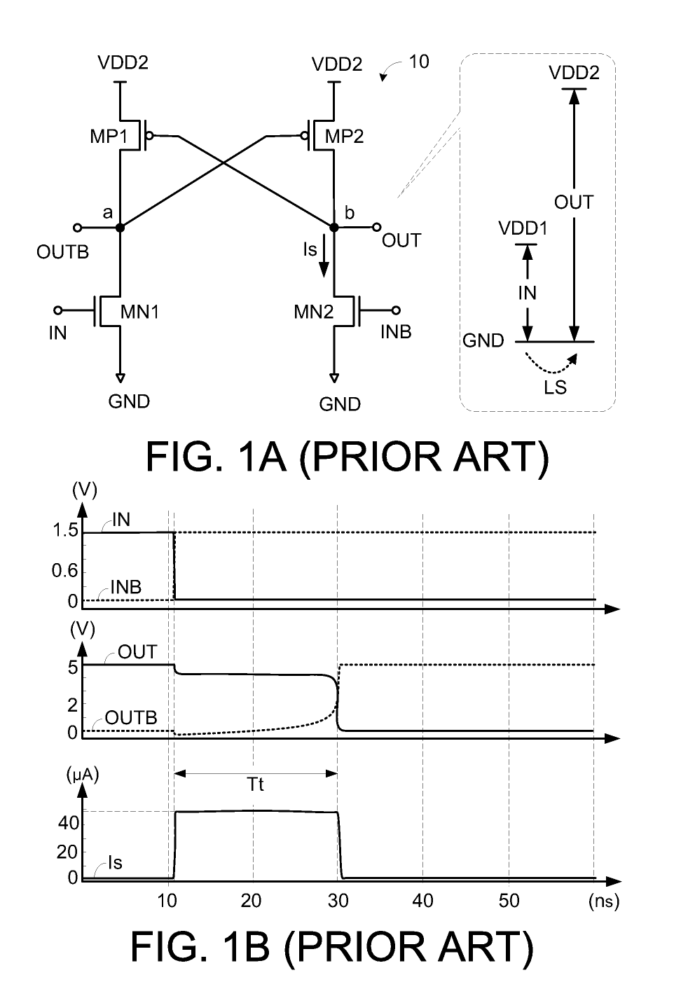

### DETAILED DESCRIPTION OF PREFERRED EMBODIMENTS

The present invention provides a level shifter. The transistor of the level shifter has a smaller size. Consequently, the layout area of the level shifter is largely reduced. In addition, the transition period of the output signal OUT is shortened, and the power consumption is reduced.

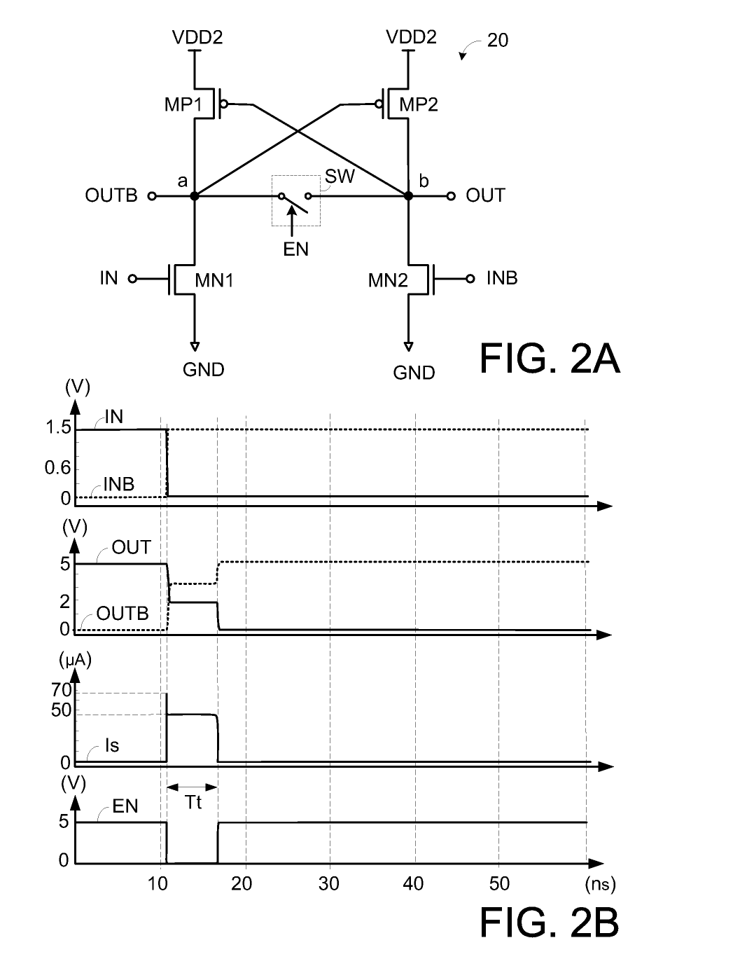

FIG. 2A is a schematic circuit diagram illustrating a level shifter according to a first embodiment of the present invention. FIG. 2B is a schematic timing waveform diagram illustrating associated signal processed by the level shifter of FIG. 2A. The level shifter 20 is used for converting an input signal IN (in the range between the voltage VDD1 and the voltage GND) into an output voltage OUT (in the range between the voltage VDD2 and the voltage GND). The voltage VDD1 is a first power supply voltage (e.g. 1.5V), the voltage VDD2 is a second power supply voltage (e.g. 5V), and the voltage GND is a ground voltage (e.g. 0V). The second power supply voltage VDD2 is higher than the first power supply voltage VDD1, and the first power supply voltage VDD1 is higher than the ground voltage GND.

As shown in FIG. 2A, the level shifter 20 comprises a switching element SW, a first P-type transistor MP1, a second P-type transistor MP2, a first N-type transistor MN1, and a second N-type transistor MN2. In this embodiment, the switching element SW is implemented by a P-type transistor, wherein the drain terminal and the source terminal are two conducting terminals of the switching element SW and the gate terminal is a control terminal of the switching element SW. Alternatively, in some other embodiments, the switching element SW is implemented by an N-type transistor.

The source terminal of the first P-type transistor MP1 is connected to the second power supply voltage VDD2. The drain terminal of the first P-type transistor MP1 is connected to a first node (a). The gate terminal of the first P-type transistor MP1 is connected to a second node (b). The source terminal of the second P-type transistor MP2 is connected to the second power supply voltage VDD2. The drain terminal of the second P-type transistor MP2 is connected to the second node (b). The gate terminal of the second P-type transistor MP2 is connected to the first node (a).

The drain terminal of the first N-type transistor MN1 is connected to the first node (a). The source terminal of the first N-type transistor MN1 is connected to the ground voltage GND. The gate terminal of the first N-type transistor MN1 receives the input signal IN. The drain terminal of the second N-type transistor MN2 is connected to the second node (b). The source terminal of the second N-type transistor MN2 is connected to the ground voltage GND. The gate terminal of the second N-type transistor MN2 receives an inverted input signal INB. The first node (a) is served as a first output terminal and generates an inverted output signal OUTB. The second node (b) is served as a second output terminal and generates the output signal OUT.

In comparison with the conventional level shifter, the level shifter 20 of this embodiment further comprises the switching element SW. The control terminal of the switching element SW receives an enabling signal EN. The two conducting terminals of the switching element SW are connected to the first node (a) and the second node (b), respectively.

During the transition period of the output signal OUT and the inverted output signal OUTB, the switching element SW is shortly enabled for a specified time interval. Consequently, the switching element SW is turned on, and a voltage difference between the first node (a) and the second node (b) is decreased. Next, the switching element SW is disabled, so that the switching element SW is turned off. In this way, the short-circuit current is largely reduced, and the transition period of the output signal OUT is shortened.

In case that the input signal IN is 1.5V and the inverted input signal INB is 0V (i.e. a steady state), the switching element SW is disabled, the first N-type transistor MN1 and the second P-type transistor MP2 are turned on, and the second N-type transistor MN2 and the first P-type transistor MP1 are turned off. Consequently, the magnitude of the output signal OUT is equal to the magnitude of the second power supply voltage VDD2 (i.e. 5V), and the magnitude of the inverted output signal OUTB is equal to magnitude of the ground voltage GND (i.e. 0V).

In case that the input signal IN is 0V and the inverted input signal INB is 1.5V (i.e. the steady state), the switching element SW is disabled, the first N-type transistor MN1 and the second P-type transistor MP2 are turned off, and the second N-type transistor MN2 and the first P-type transistor MP1 are turned on. Consequently, the magnitude of the output signal OUT is equal to the magnitude of the ground voltage GND (i.e. 0V), and the magnitude of the inverted output signal OUTB is equal to magnitude of the second power supply voltage VDD2 (i.e. 5V).

Please refer to FIG. 2B. During the transient period of changing the input signal IN from 1.5V to 0V and changing the inverted input signal INB from 0V to 1.5V, the switching element SW is enabled by the enabling signal EN. Consequently, the switching element SW is turned on. Under this circumstance, the charge-sharing action results in reduction of the voltage difference between the first node (a) and the second node (b). For example, the output signal OUT is decreased from 5V to 2V, and the inverted output signal OUTB is increased from 0V to 3V.

Moreover, when the switching element SW is disabled by the enabling signal EN, the output signal OUT is immediately decreased from 2V to 0V, and the inverted output signal OUTB is immediately increased from 3V to 5V. Consequently, the transition period Tt of the output signal OUT is completed. In other words, the time period of closing the switching element SW may be considered as the transition period Tt of the output signal OUT.

As shown in FIG. 2B, the transition period Tt of the output signal OUT and the inverted output signal OUTB is about 6 ns, the maximum value of the short-circuit current is about 68 μA, and the average short-circuit current is about 4.8 μA. In comparison with the conventional level shifter, the transition period of the output signal OUT of the present level shifter is shortened, and the power consumption of the present level shifter is reduced.

Moreover, since the charge-sharing action may reduce the voltage difference between the first node (a) and the second node (b) during the transition period of the output signal OUT, it is not necessary to specially design the size ratio of the N-type transistor to the P-type transistor. In other words, the level shifter of the present invention may be implemented by small-sized N-type transistors and P-type transistors. Consequently, the level shifter of the present invention is capable of smoothly resulting in the transition of the output signal OUT and the inverted output signal OUTB. In other words, the layout area of the level shifter can be largely reduced.

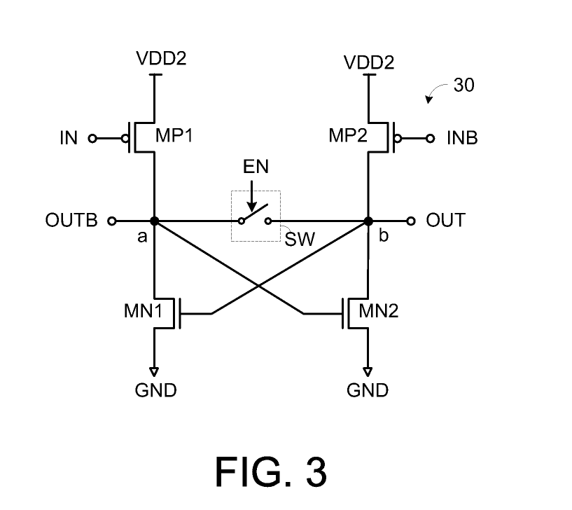

FIG. 3 is a schematic circuit diagram illustrating a level shifter according to a second embodiment of the present invention. The level shifter 30 is used for converting an input signal IN (in the range between the voltage VDD1 and the voltage GND) into an output voltage OUT (in the range between the voltage VDD2 and the voltage GND). The voltage VDD1 is a first power supply voltage (e.g. 3.5V), the voltage VDD2 is a second power supply voltage (e.g. 5V), and the voltage GND is a ground voltage (e.g. 0V). The second power supply voltage VDD2 is higher than the first power supply voltage VDD1, and the first power supply voltage VDD1 is higher than the ground voltage GND.

As shown in FIG. 3A, the level shifter 30 comprises a switching element SW, a first P-type transistor MP1, a second P-type transistor MP2, a first N-type transistor MN1, and a second N-type transistor MN2. In this embodiment, the switching element SW is implemented by an N-type transistor or a P-type transistor. The drain terminal and the source terminal are two conducting terminals of the switching element SW, and the gate terminal is a control terminal of the switching element SW.

The source terminal of the first P-type transistor MP1 is connected to the second power supply voltage VDD2. The drain terminal of the first P-type transistor MP1 is connected to a first node (a). The gate terminal of the first P-type transistor MP1 receives the input signal IN. The source terminal of the second P-type transistor MP2 is connected to the second power supply voltage VDD2. The drain terminal of the second P-type transistor MP2 is connected to the second node (b). The gate terminal of the second P-type transistor MP2 receives an inverted input signal INB.

The drain terminal of the first N-type transistor MN1 is connected to the first node (a). The source terminal of the first N-type transistor MN1 is connected to the ground voltage GND. The gate terminal of the first N-type transistor MN1 is connected to the second node (b). The drain terminal of the second N-type transistor MN2 is connected to the second node (b). The source terminal of the second N-type transistor MN2 is connected to the ground voltage GND. The gate terminal of the second N-type transistor MN2 is connected to the first node (a). The first node (a) is served as a first output terminal and generates an inverted output signal OUTB. The second node (b) is served as a second output terminal and generates the output signal OUT.

The control terminal of the switching element SW receives an enabling signal EN. The two conducting terminals of the switching element SW are connected to the first node (a) and the second node (b), respectively.

During the transition period of the output signal OUT and the inverted output signal OUTB, the switching element SW is shortly enabled. Consequently, the switching element SW is turned on, and a voltage difference between the first node (a) and the second node (b) is decreased. Next, the switching element SW is disabled, so that the switching element SW is turned off. In this way, the short-circuit current is largely reduced, and the transition period of the output signal OUT is shortened. The operations of the level shifter of this embodiment are similar to those of the first embodiment, and are not redundantly described herein.

From the above descriptions, the present invention provides a level shifter. The layout area of the level shifter is largely reduced, the transition period of the output signal OUT is shortened, and the power consumption is reduced.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A level shifter for converting an input signal into an output signal, the level shifter comprising:
a first transistor, having a first drain terminal connected to a first node, a first gate terminal receiving the input signal, and a first source terminal connected to a first power supply voltage;
a second transistor, having a second drain terminal connected to a second node, a second gate terminal receiving an inverted input signal, and a second source terminal connected to the first power supply voltage;
a third transistor, having a third source terminal connected to a second power supply voltage, a third drain terminal connected to the first node, and a third gate terminal connected to the second node;
a fourth transistor, having a fourth source terminal connected to the second power supply voltage, a fourth drain terminal connected to the second node, and a fourth gate terminal connected to the first node, wherein the first node is served as a first output terminal for generating an inverted output signal, and the second node is served as a second output terminal for generating the output signal; and
a switching element, connected between the first node and the second node, wherein the switching element is controlled according to an enabling signal,
wherein when a voltage level of the input signal is changed, the switching element is turned on for a time interval according to the enabling signal, so that a voltage level of the output signal is changed.

2. The level shifter as claimed in claim 1, wherein the first transistor and the second transistor are N-type transistors, and the third transistor and the fourth transistor are P-type transistors.

3. The level shifter as claimed in claim 2, wherein the second power supply voltage is higher than the first power supply voltage.

4. The level shifter as claimed in claim 3, wherein the input voltage is in a range between 1.5V and 0V, the output voltage is in a range between 5V and 0V, the second power supply voltage is 5V, and the first power supply voltage is 0V.

5. The level shifter as claimed in claim 2, wherein when the input signal has a high voltage level, the inverted input signal has a low voltage level and the switching element is turned off, the first transistor and the fourth transistor are turned on, and the second transistor and the third transistor are turned off, so that the output signal is equal to the second power supply voltage and the inverted output signal is equal to the first power supply voltage.

6. The level shifter as claimed in claim 5, wherein when the input signal is changed from the high voltage level to the low voltage level, the switching element is turned on for the time interval, so that a charge-sharing action between the first node and the second node results in reduction of a voltage difference between the first node and the second node.

7. The level shifter as claimed in claim 6, wherein after the input signal is changed from the high voltage level to the low voltage level and the switching element is turned on for the time interval, the output signal is equal to the first power supply voltage and the inverted output signal is equal to the second power supply voltage.

8. The level shifter as claimed in claim 7, wherein when the input signal has the low voltage level, the inverted input signal has the high voltage level and the switching element is turned off, the first transistor and the fourth transistor are turned off, but the second transistor and the third transistor are turned on, so that the output signal is equal to the first power supply voltage and the inverted output signal is equal to the second power supply voltage.

9. The level shifter as claimed in claim 1, wherein the switching element is transistor, including a gate of the switching element receiving the enabling signal, a drain terminal of the switching element connected to the first node, and a source terminal of the switching element connected to the second node.

10. The level shifter as claimed in claim 1, wherein the first transistor and the second transistor are P-type transistors, and the third transistor and the fourth transistor are N-type transistors.

11. The level shifter as claimed in claim 10, wherein the first power supply voltage is higher than the second power supply voltage.

12. The level shifter as claimed in claim 11, wherein the input voltage is in a range between 3.5V and 5V, the output voltage is in a range between 5V and 0V, the second power supply voltage is 0V, and the first power supply voltage is 5V.

13. The level shifter as claimed in claim 10, wherein when the input signal has a low voltage level, the inverted input signal has a high voltage level and the switching element is turned off, the first transistor and the fourth transistor are turned on, and the second transistor and the third transistor are turned off, so that the output signal is equal to the second power supply voltage and the inverted output signal is equal to the first power supply voltage.

14. The level shifter as claimed in claim 13, when while the input signal is changed from the low voltage level to the high voltage level, the switching element is turned on for the time interval, so that a charge-sharing action between the first node and the second node results in reduction of a voltage difference between the first node and the second node.

15. The level shifter as claimed in claim 14, wherein after the input signal is changed from the low voltage level to the high voltage level and the switching element is turned on for the time interval, the output signal is equal to the first power supply voltage and the inverted output signal is equal to the second power supply voltage.

16. The level shifter as claimed in claim 15, wherein when the input signal has the high voltage level, the inverted input signal has the low voltage level and the switching element is turned off, the first transistor and the fourth transistor are turned off, but the second transistor and the third transistor are turned on, so that the output signal is equal to the first power supply voltage and the inverted output signal is equal to the second power supply voltage.
